(19) United States
(12) Patent Application Publication
(10) Pub. No.: US 2023/0376349 A1
(43) Pub. Date: Nov. 23, 2023

(54) DATA PROCESSOR AND METHOD FOR PROCESSING DATA

(71) Applicant: TOYOTA JIDOSHA KABUSHIKI KAISHA, Toyota-shi (JP)

(72) Inventor: Hidetaka FUSE, Tokyo-to (JP)

(73) Assignee: TOYOTA JIDOSHA KABUSHIKI KAISHA, Toyota-shi (JP)

(21) Appl. No.: 18/181,316

(22) Filed: Mar. 9, 2023

(30) Foreign Application Priority Data
May 17, 2022 (JP) 2022-080969

(51) Int. Cl. G06F 9/48

(52) U.S. Cl. CPC G06F 9/4887

(57) ABSTRACT

A data processor repeats a set of processes every cycle time. The processes include a first process to obtain data from a sensor and are executed in predetermined order. The data processor estimates a non-inferior interval during which a cause of inferiority of the data obtained in the first process is removed by operation of a device disposed near the sensor, and sets a delay time during which none of the set of processes is executed, before execution of the first process, when a scheduled execution time of the first process included in the set of processes started at a predetermined time is outside the non-inferior interval. The delay time is not longer than a period from a scheduled end time of the set of processes until a start time of the set of processes that follows the set of processes started at the predetermined time.

### FIELD

The present disclosure relates to a data processor, a method, and a computer program for processing data obtained from a sensor.

### BACKGROUND

When travel of a vehicle is controlled on the basis of data obtained from a sensor, it is preferable to execute a process related to control of travel of the vehicle on data generated by the sensor and including as little noise and loss as possible in order to control travel of the vehicle appropriately.

Japanese Unexamined Patent Publication No. 8-58529 describes a wiper controller of a vehicle that captures images of an object outside the vehicle with a camera through a windshield on which raindrops are wiped off by moving windshield wipers. The wiper controller modifies the moving speed of the windshield wipers when predicted positions of the windshield wipers at capturing timing are within a capture area.

### SUMMARY

When windshield wipers are moving to wipe raindrops off a windshield, an in-vehicle sensor disposed on the inner side of the windshield may output inferior data on the surroundings of the vehicle, depending on timing. It is obviously desirable not to use such inferior data for a process related to control of travel of a vehicle.

It is an object of the present disclosure to provide a data processor that can obtain data degraded as little as possible from a sensor and use the data for a process.

A data processor according to the present disclosure includes a cycle execution unit that repeats a set of processes every cycle time. The processes include a first process to obtain data from a sensor and are executed in predetermined order. The data processor further includes an estimation unit that estimates a non-inferior interval during which a cause of inferiority of the data obtained in the first process is removed by operation of a device disposed near the sensor; and a delay unit that sets a delay time during which none of the set of processes is executed, before execution of the first process, when a scheduled execution time of the first process included in the set of processes started at a predetermined time is outside the non-inferior interval. The delay time is not longer than a period from a scheduled end time of the set of processes until a start time of the set of processes that follows the set of processes started at the predetermined time.

The data processor according to the present disclosure preferably further includes a forbidding unit that forbids execution of a process using data obtained by the first process delayed by setting the delay time, when a scheduled execution time of the delayed first process precedes the non-inferior interval.

The delay unit of the data processor according to the present disclosure preferably sets the delay time not shorter than a period from the scheduled execution time of the first process until a start time of the non-inferior interval.

A method for processing data according to the present disclosure includes repeating a set of processes every cycle time. The processes include a first process to obtain data from a sensor and are executed in predetermined order. The method further includes estimating a non-inferior interval during which a cause of inferiority of the data obtained in the first process is removed by operation of a device disposed near the sensor; and setting a delay time during which none of the set of processes is executed, before execution of the first process, when a scheduled execution time of the first process included in the set of processes started at a predetermined time is outside the non-inferior interval. The delay time is not longer than a period from a scheduled end time of the set of processes until a start time of the set of processes that follows the set of processes started at the predetermined time.

A computer program for processing data stored in a non-transitory computer-readable medium according to the present disclosure causes a computer to execute processing including repeating a set of processes every cycle time. The processes include a first process to obtain data from a sensor and are executed in predetermined order. The processing further includes estimating a non-inferior interval during which a cause of inferiority of the data obtained in the first process is removed by operation of a device disposed near the sensor; and setting a delay time during which none of the set of processes is executed, before execution of the first process, when a scheduled execution time of the first process included in the set of processes started at a predetermined time is outside the non-inferior interval. The delay time is not longer than a period from a scheduled end time of the set of processes until a start time of the set of processes that follows the set of processes started at the predetermined time.

The data processor according to the present disclosure can obtain data degraded as little as possible from a sensor and use the data for a process.

### BRIEF DESCRIPTION OF DRAWINGS

FIG. 1 schematically illustrates the configuration of a vehicle equipped with a data processor.

FIG. 2 illustrates the hardware configuration of the data processor.

FIG. 3 illustrates an example of a schedule of cyclically executed processes.

FIG. 4 illustrates an example of a timing chart of operation of windshield wipers.

FIG. 5 is a functional block diagram of a processor included in the data processor.

FIG. 6 illustrates an example of cyclic processes.

FIG. 7 is a flowchart of data processing.

### DESCRIPTION OF EMBODIMENTS

A data processor that can obtain data from a sensor so as not to be affected by operation of a device disposed near the sensor will now be described in detail with reference to the attached drawings. The data processor repeats a set of processes every cycle time. The processes include a first process to obtain data from a sensor and are executed in predetermined order. The data processor estimates a non-inferior interval during which a cause of inferiority of the data obtained in the first process is removed by operation of a device disposed near the sensor. The data processor then sets a delay time during which none of the set of processes is executed, before execution of the first process, when a scheduled execution time of the first process included in the set of processes started at a predetermined time is outside the non-inferior interval. The set delay time is not longer than a period from a scheduled end time of the set of processes until a start time of the set of processes that follows the set of processes started at the predetermined time.

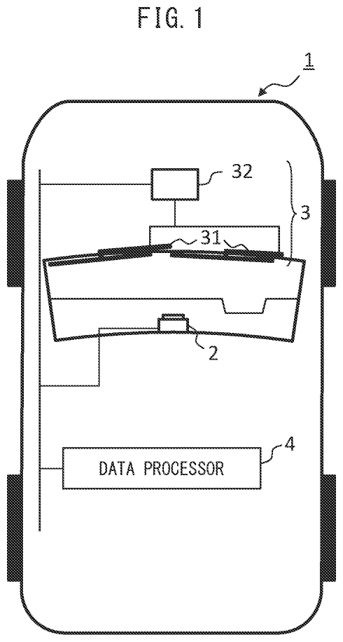

FIG. 1 schematically illustrates the configuration of a vehicle 1 equipped with a data processor.

The vehicle 1 includes an environmental camera 2, a wiper device 3, and a data processor 4. The environmental camera 2 and the wiper device 3 are communicably connected to the data processor 4 via an in-vehicle network conforming to a standard such as a controller area network.

The environmental camera 2 is an example of a sensor for generating data representing the surroundings of the vehicle 1. The environmental camera 2 includes a two-dimensional detector constructed from an array of optoelectronic transducers, such as CCD or C-MOS, having sensitivity to visible light and a focusing optical system that forms an image of a target region on the two-dimensional detector. The environmental camera 2 is disposed, for example, in a front and upper area in the vehicle interior and oriented forward, takes a picture of the surroundings of the vehicle 1 through a windshield every predetermined capturing period (e.g., 1/30 to 1/10 seconds), and outputs data representing the surroundings of the vehicle 1.

The wiper device 3 is an example of the device disposed near the sensor. Both the environmental camera 2 and the wiper device 3 are disposed near the windshield. In other words, the wiper device 3 is disposed near the environmental camera 2.

The wiper device 3 includes windshield wipers 31 and a wiper controller 32. The wipers 31 each include a stick-like soft member, such as rubber, and wipe unclearness off the outer surface of the windshield by moving the soft members at predetermined intervals around predetermined positions near an edge of the windshield as fulcrums so that the soft members are in contact with the outer surface of the windshield. The wiper controller 32 controls operation of the wipers 31 so that the wipers 31 move with higher frequency as more rainfall is sensed by a raindrop sensor (not illustrated) that senses rainfall around the vehicle 1. The wiper controller 32 may control operation of the wipers 31 in response to a driver's operation of a wiper switch (not illustrated).

Operation of the wiper device 3 wipes unclearness off the outer surface of the windshield through which light beams pass at taking a picture of the surroundings of the vehicle 1 with the environmental camera 2, and thereby removes a cause of inferiority of data outputted by the environmental camera 2.

The data processor 4 is an electronic control unit (ECU) including a communication interface, a memory, and a processor. The data processor 4 repeats a set of processes in predetermined order every cycle time to process data obtained from the environmental camera 2 when unclearness is wiped off the windshield by the wiper device 3.

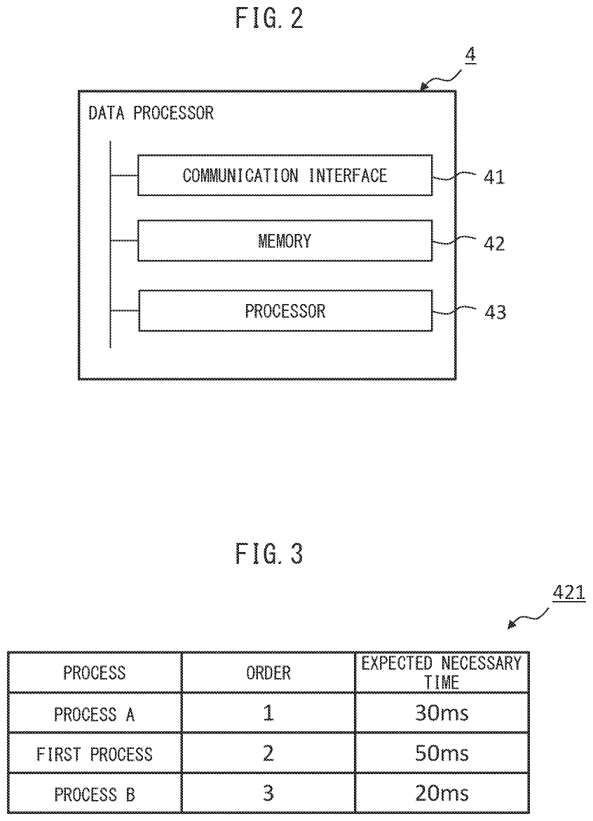

FIG. 2 illustrates the hardware configuration of the data processor 4. The data processor 4 includes a communication interface 41, a memory 42, and a processor 43.

The communication interface 41, which is an example of a communication unit, includes a communication interface circuit for connecting the data processor 4 to the in-vehicle network. The communication interface 41 provides received data for the processor 43, and outputs data provided from the processor 43 to an external device.

The memory 42, which is an example of a storage unit, includes volatile and nonvolatile semiconductor memories. The memory 42 stores various types of data used for processing by the processor 43, such as a schedule in which each of processes is associated with an expected necessary time and a position in the order of execution of the processes in a cycle, the cycle time of the processes that are repeated, and a timing chart representing operating timing of the wiper device 3 for each operating mode. The memory 42 also stores various application programs, such as a program for data processing to process data.

FIG. 3 illustrates an example of a schedule of cyclically executed processes. The memory 42 stores a schedule 421 in which each of the processes is associated with an expected necessary time and a position in the order of execution of the processes in a cycle.

In the schedule 421, the set of processes includes a process A, a first process, and a process B. For example, the process A is to communicate with a device outside the vehicle via a data communication module (not illustrated), the first process is to obtain data from the environmental camera 2, and the process B is to convert the data obtained in the first process. A set of processes executed cyclically in accordance with the schedule 421 will be referred to herein as “cyclic processes.”

The process A is associated with position “1” and expected necessary time “30 ms.” Thus the process A starts at the beginning of a predetermined length of cycle time (e.g., 150 ms), i.e., 0 ms after the start, and is expected to end 30 ms after the start of the process A, i.e., 30 ms after the beginning of the cycle time.

The first process is associated with position “2” and expected necessary time “50 ms.” Thus the first process starts at the end time of the process of position “1” (process A) in the cycle time, i.e., 30 ms after the beginning of the cycle time, and is expected to end 50 ms after the start of the first process, i.e., 80 ms after the beginning of the cycle time.

The process B is associated with position “3” and expected necessary time “20 ms.” Thus the process B starts at the end time of the process of position “2” (first process) in the cycle time, i.e., 80 ms after the beginning of the cycle time, and is expected to end 20 ms after the start of the process B, i.e., 100 ms after the beginning of the cycle time.

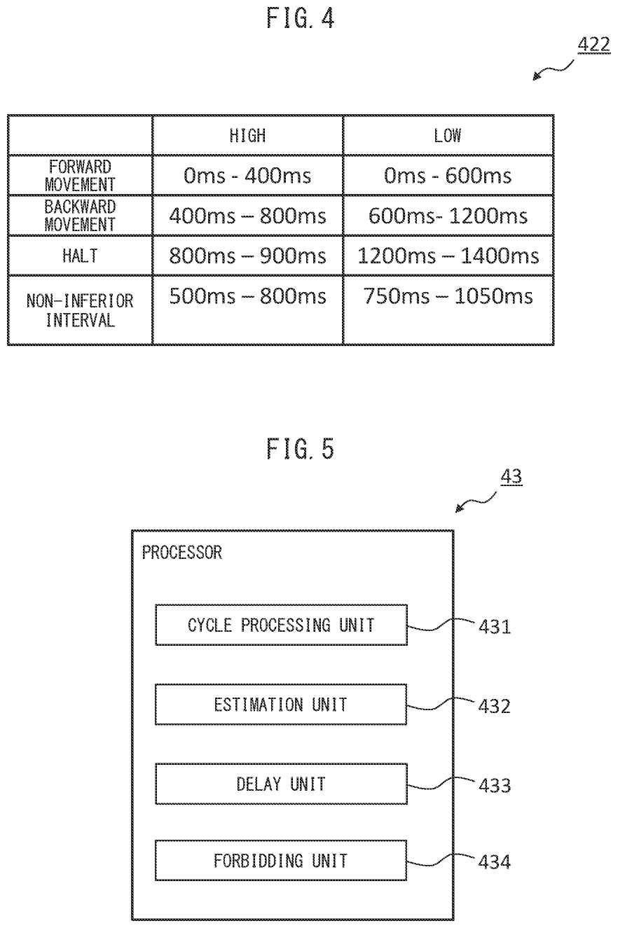

FIG. 4 illustrates an example of a timing chart of operation of the windshield wipers. The memory 42 stores a timing chart 422 representing operating timing of the wiper device 3 for each operating mode.

As operating modes of the wiper device 3, the timing chart 422 includes “high” mode in which the frequency of wiping is relatively high, and “low” mode in which the frequency of wiping is relatively low. “High” mode is associated with “0 ms to 400 ms” as the interval of forward movement (interval during which each wiper 31 moves from its housing position to a far end), “400 ms to 800 ms” as that of backward movement (interval during which each wiper 31 returns from the far end to the housing position), and “800 ms to 900 ms” as that of a halt (interval from the return of each wiper 31 from the far end to the housing position until the start of movement to the far end). Each of these intervals of operation is expressed with the start time and the end time defined using the periods from the start time of operation at the corresponding mode. After the end of sequential operation from forward movement to a halt, the next sequential operation is executed from the end time of the halt (900 ms after the start of operation), which is the new start time. Thereafter, operation continues similarly.

“Low” mode is associated with “0 ms to 600 ms,” “600 ms to 1200 ms,” and “1200 ms to 1400 ms” as the intervals of forward movement, backward movement, and a halt, respectively.

In the timing chart 422, the operating timing of each operating mode may be expressed using the periods of operation of the wipers 31 (forward movement, backward movement, and a halt). More specifically, for example, the operating timing in “high” mode may be expressed as follows: “the periods of forward movement, backward movement, and a halt are 400 ms, 400 ms, and 100 ms, respectively.”

In the timing chart 422, each operating mode is further associated with a non-inferior interval. As the non-inferior interval is appropriately set an interval during which operation of the wiper device 3 wipes unclearness off the outer surface of the windshield and thereby removes a cause of inferiority of data outputted by the environmental camera 2. In the timing chart 422, the non-inferior interval is set so as to correspond to a predetermined period from when each wiper 31 returning from the far end to the housing position passes the position of the environmental camera 2. The non-inferior interval is expressed with the start time and the end time defined using the periods from the start time of operation at the corresponding mode. The non-inferior interval may be expressed with its start time, which is defined using the period from the start time of operation at the corresponding mode, and the length of the period from the start time to the end time. For example, the non-inferior interval in “high” mode may be expressed as follows: “the start time is 500 ms after the start of operation, and the length is 300 ms.”

The wiper controller 32 starts controlling operation of the wipers 31, in response to rainfall sensed by the raindrop sensor or operation of the wiper switch, in a predetermined operating mode in accordance with the timing chart 422 at a predetermined time, which is the start time of operation. The data processor 4 can obtain the operating mode and the start time of operation of the wipers 31 from the wiper controller 32, and determine the operating state of the wipers 31 by referring to the timing chart 422.

FIG. 5 is a functional block diagram of the processor 43 included in the data processor 4.

As its functional blocks, the processor 43 of the data processor 4 includes a cycle processing unit 431, an estimation unit 432, a delay unit 433, and a forbidding unit 434. These units included in the processor 43 are functional modules implemented by a computer program stored in the memory 42 and executed by the processor 43. The computer program for achieving the functions of the units of the processor 43 may be provided in a form recorded on a computer-readable portable storage medium, such as a semiconductor memory, a magnetic medium, or an optical medium. Alternatively, the units included in the processor 43 may be implemented in the data processor 4 as separate integrated circuits, microprocessors, or firmware.

The cycle processing unit 431 repeats a set of processes every cycle time (e.g., 150 ms). The processes include a first process to obtain data from the environmental camera 2 and are executed in the order specified in the schedule 421 stored in the memory 42. The cycle processing unit 431 may be implemented as a function of a real-time OS executed by the processor 43. In addition to the first process, the set of processes may further include transmission of a control signal to a travel mechanism (not illustrated) of the vehicle 1, transmission of display data to a meter display (not illustrated), communication with a device outside the vehicle via the data communication module (not illustrated), and format conversion of the obtained data.

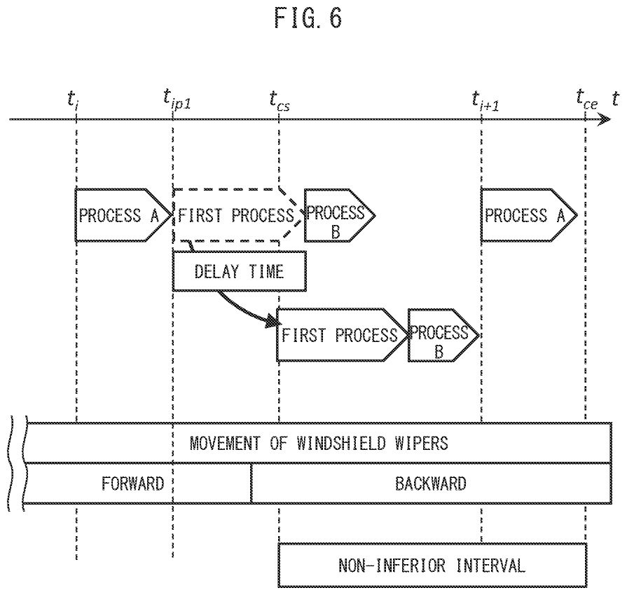

FIG. 6 illustrates an example of cyclic processes. It is scheduled to execute the process A first and thereafter the first process in cyclic processes started from time L.

The estimation unit 432 estimates a non-inferior interval during which a cause of inferiority of data obtained from the environmental camera 2 is removed by operation of the wiper device 3.

The estimation unit 432 obtains the operating mode and the start time of operation of the wipers 31 from the wiper controller 32 via the in-vehicle network. The estimation unit 432 can calculate the time elapsed from the start time of operation until a predetermined time, and determine the operating state of the wipers 31 at the predetermined time by referring to the timing chart 422 stored in the memory 42.

The estimation unit 432 determines the operating state of the wipers 31 at each time within the interval illustrated in FIG. 6, and estimates that the non-inferior interval is from time t_{cs} until time t_{ce} (e.g., from 70 ms after time tᵢ until 190 ms after time tᵢ).

The estimation unit 432 may change the non-inferior interval from that stored in the memory 42, depending on rainfall sensed by the raindrop sensor. For example, when the amount of sensed rainfall is greater than that of standard rainfall in the operating mode applied to the wipers 31, the windshield probably becomes wet again with raindrops sooner than expected after unclearness near the environmental camera 2 is wiped off by backward movement of the wipers 31. In this case, the estimation unit 432 may change the end time of the non-inferior interval to earlier timing. Conversely, when the amount of sensed rainfall is less than that of standard rainfall in the operating mode applied to the wipers 31, the estimation unit 432 may change the end time of the non-inferior interval to later timing.

The delay unit 433 sets a delay time during which none of the cyclic processes is executed, before execution of the first process, when a scheduled execution time of the first process included in the cyclic processes started at a predetermined time is outside the non-inferior interval.

In the example of FIG. 6, time tᵢₚ₁ (30 ms after time tᵢ), which is the scheduled execution time of the first process included in cyclic processes started at time is outside the non-inferior interval. The delay unit 433 delays the scheduled execution time of the first process, and sets the period from time tᵢₚ₁ until the scheduled execution time of the delayed first process as the delay time. In the example of FIG. 6, the delay unit 433 sets the delayed scheduled execution time of the first process at time t_{cs} (70 ms after time tᵢ), which is the start time of the non-inferior interval.

The delay unit 433 sets the delay time not longer than a period (50 ms) from a scheduled end time of the cyclic processes (100 ms after time tᵢ) until a start time tᵢ₊₁ (150 ms after time tᵢ) of the cyclic processes that follow the cyclic processes started at time tᵢ. By setting the delay time in this way, the data processor 4 can start the next cyclic processes without being affected by execution of the delayed first process.

The delay unit 433 may set the delay time not shorter than a period (40 ms) from time tᵢₚ₁ (30 ms after time tᵢ), which is the scheduled execution time of the first process, until time t_{cs} (70 ms after time tᵢ), which is the start time of the non-inferior interval. By setting the delay time in this way, the data processor 4 can include the scheduled execution time of the first process in the non-inferior interval, obtain data degraded as little as possible, and use the data for a process.

The forbidding unit 434 forbids execution of a process using data obtained by the first process delayed by setting the delay time, when the scheduled execution time of the delayed first process precedes the non-inferior interval.

In the example of FIG. 6, the process B corresponds to the process using data obtained by the first process. In the example of FIG. 6, the forbidding unit 434 does not forbid execution of the process B because the scheduled execution time of the delayed first process is within the non-inferior interval. However, when the scheduled execution time of the delayed first process is outside the non-inferior interval, the forbidding unit 434 forbids execution of the process B.

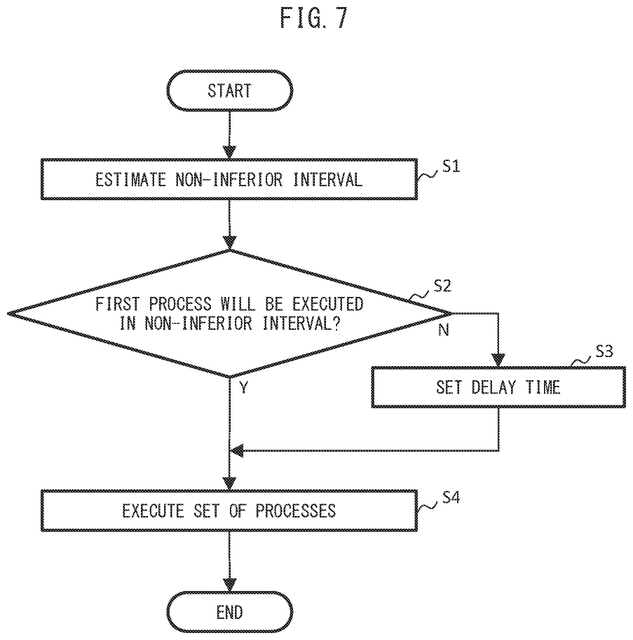

FIG. 7 is a flowchart of data processing. While cyclic processes are required, the data processor 4 repeats the processing illustrated in FIG. 7 every cycle time.

First, the estimation unit 432 of the processor 43 of the data processor 4 estimates a non-inferior interval during which a cause of inferiority of data obtained from the environmental camera 2 is removed by operation of the wiper device 3 (step S1).

Next, the delay unit 433 of the processor 43 determines whether the start time of a first process included in a set of processes started at a predetermined time is within the non-inferior interval (step S2). The first process is to obtain data from the environmental camera 2.

When it is determined that the start time of the first process is outside the non-inferior interval (No in step S2), the delay unit 433 sets a delay time during which none of the set of processes is executed, before execution of the first process (step S3), and proceeds to step S4 described below.

When it is determined that the start time of the first process is within the non-inferior interval (Yes in step S2), the cycle processing unit 431 executes the set of processes in predetermined order (step S4), and terminates data processing in the current cycle time.

By operating as described above, the data processor 4 can obtain data degraded as little as possible from a sensor and use the data for a process.

According to a modified example, the vehicle 1 may include a light detection and ranging (LiDAR) sensor as the sensor for generating data representing the surroundings of the vehicle 1. The LiDAR sensor generates a range image whose pixels each have a value depending on the distance to an object represented in the pixel, based on the surroundings of the vehicle 1. In addition, the window to which the sensor is attached is not limited to a front window, and may be a rear window or a side window.

As the device disposed near the sensor, the vehicle 1 may include a window heater that heats a heating element attached to a window of the vehicle 1 to remove fogginess of the window. The estimation unit 432 estimates a non-inferior interval during which fogginess of the window causing inferiority of data is removed by operation of the window heater. The estimation unit 432 may estimate the non-inferior interval so that the interval from heating of the heating element until the start time of the non-inferior interval is longer as the difference in temperature between the inside and outside of the vehicle 1 is greater.

As the device disposed near the sensor, the vehicle 1 may include a window washer that sprays washing liquid over a window of the vehicle 1 to remove unclearness of the window. The estimation unit 432 estimates a non-inferior interval during which unclearness of the window causing inferiority of data is removed by operation of the window washer.

Note that those skilled in the art can make various changes, substitutions, and modifications without departing from the spirit and scope of the present disclosure.

What is claimed is:

1. A data processor comprising a processor configured to
repeat a set of processes every cycle time, the processes including a first process to obtain data from a sensor and being executed in predetermined order;
estimate a non-inferior interval during which a cause of inferiority of the data obtained in the first process is removed by operation of a device disposed near the sensor; and
set a delay time during which none of the set of processes is executed, before execution of the first process, when a scheduled execution time of the first process included in the set of processes started at a predetermined time is outside the non-inferior interval, the delay time being not longer than a period from a scheduled end time of the set of processes until a start time of the set of processes that follows the set of processes started at the predetermined time.

2. The data processor according to claim 1, wherein the processor is further configured to forbid execution of a process using data obtained by the first process delayed by setting the delay time, when a scheduled execution time of the delayed first process precedes the non-inferior interval.

3. The data processor according to claim 1, wherein the processor sets the delay time not shorter than a period from the scheduled execution time of the first process until a start time of the non-inferior interval.

4. A method for processing data, comprising:
repeating a set of processes every cycle time, the processes including a first process to obtain data from a sensor and being executed in predetermined order;
estimating a non-inferior interval during which a cause of inferiority of the data obtained in the first process is removed by operation of a device disposed near the sensor; and
setting a delay time during which none of the set of processes is executed, before execution of the first process, when a scheduled execution time of the first process included in the set of processes started at a predetermined time is outside the non-inferior interval, the delay time being not longer than a period from a scheduled end time of the set of processes until a start time of the set of processes that follows the set of processes started at the predetermined time.

5. A non-transitory computer-readable medium storing a computer program for processing data, the computer program causing a computer to execute processing comprising:
repeating a set of processes every cycle time, the processes including a first process to obtain data from a sensor and being executed in predetermined order;
estimating a non-inferior interval during which a cause of inferiority of the data obtained in the first process is removed by operation of a device disposed near the sensor; and
setting a delay time during which none of the set of processes is executed, before execution of the first process, when a scheduled execution time of the first process included in the set of processes started at a predetermined time is outside the non-inferior interval, the delay time being not longer than a period from a scheduled end time of the set of processes until a start time of the set of processes that follows the set of processes started at the predetermined time.
